(19) United States
(12) Patent Application Publication
(10) Pub. No.: US 2015/0345642 A1
(43) Pub. Date: Dec. 3, 2015

(54) THIN FILM COATING ON MECHANICAL FACE SEALS

(71) Applicant: CATERPILLAR INC., PEORIA, IL (US)

(72) Inventors: CONNOR JOHN HAAS, PEORIA, IL (US); STEVEN CHARLES TAYLOR, GERMANTOWN HILLS, IL (US); DANIEL EDWARD MATHIEN, PEORIA, IL (US); DANIEL PATRICK VERTENTEN, AURORA, IL (US)

(73) Assignee: CATERPILLAR INC., PEORIA, IL (US)

(21) Appl. No.: 14/290,889

(22) Filed: May 29, 2014

(51) Int. Cl. F16J 15/34; E21B 10/25; C23C 28/00; C23C 14/06; C23C 14/14

(52) U.S. Cl. CPC F16J 15/3496; C23C 14/0611; C23C 14/14; C23C 28/343; E21B 10/25

(57) ABSTRACT

A seal is disclosed. The seal has a first surface and a second surface disposed in a plane generally parallel to the first surface. At least one of the first surface and the second surface is at least partially coated with a film that includes an adhesion layer, a transition layer, and an amorphous diamond-like (a-DLC) layer.

### TECHNICAL FIELD

The present disclosure generally relates to mechanical face seals, and more particularly, to mechanical face seals coated with thin films.

### BACKGROUND

Many applications inherently subject machine, components to extreme conditions, accelerating component wear and failure. One such application, for example, is earth boring. In earth boring, at least one rolling cone cutter is used to drill a borehole. The rolling cone cutter mounts rotatably to a shaft that is progressively lowered in the borehole as earthen formation is pulverized.

The cone's rotation with respect to the shaft is achieved using a seal assembly. Earth-boring bits may include at least one rigid seal ring disposed in a groove at the base of the shaft. This rigid seal ring has a surface that mates with a surface of a bearing sleeve located on the cone. The bearing sleeve and the rigid seal ring form a seal assembly, and they rotate relative to each other. Since the mating surfaces are metallic, they must be lubricated in order to allow seamless rotation of the cone around the shaft. Further, the lubricant must remain at the interface despite the high rotational speeds of the cone.

In earth boring, the cone is subjected to high load pressures resulting from the forces exerted on the shaft, from transient shocks that occur when crushing earthen formations, and from sliding the bit along sidewalls of the borehole. These high pressure loads may cause the seal assembly to fail. Furthermore, the high speeds at which the cone is required to rotate to ensure satisfactory earth boring performance may also cause the assembly to fail. Lastly, exposure to corrosive and abrasive particles from the crushed earthen formations may corrode the components of the seal assembly, especially if these particles get lodged at the interface between the mating surfaces.

An example method for fabricating an improved seal assembly for earth-boring bits was disclosed in U.S. Pat. No. 7,234,541 that issued to Scott et al. on Jun. 26, 2007 (“the '541 patent”). Surfaces of a mechanical face seal were coated with a diamond-like carbon (DLC) film disposed on an intermediate layer coated on the seal surfaces. Seals coated with the DLC film were reported to have increased wear resistance relative to uncoated seals.

The coated seals disclosed in the '541 patent may provide certain benefits that are particularly important for some earth boring applications. However, they may have certain drawbacks. For example, DLC coatings may delaminate during use because of poor adhesion to the underlying seal surface, even when an intermediate layer is used. The embodiments disclosed herein may help solve at least these problems.

### SUMMARY OF THE INVENTION

In one aspect, the present disclosure is directed to a seal. The seal may include a first surface and a second surface disposed in a plane generally parallel to the first surface. Additionally, at least one of the first surface and the second surface may he at least partially coated with a film. The film may include an adhesion layer, a transition layer, and an amorphous diamond-like (a-DLC) layer.

In another aspect, the present disclosure is directed to a method for fabricating a seal interface by modifying a surface of a seal ring, The method may include finishing the surface to impart to it a predetermined geometry and/or a predetermined metrology. Further, the method may include cleaning the surface after finishing and depositing thereon a first layer using physical vapor deposition (PVD) sputtering, The first layer may include a metal. Furthermore, the method may include depositing a second layer on the first layer, using PVD sputtering. The second layer may include a metal and carbon. Additionally, the method may include depositing a third layer on the second layer using plasma-assisted chemical vapor deposition (PACVD). The third layer may be an amorphous diamond-like carbon (a-DLC) layer.

### BRIEF DESCRIPTION OF THE DRAWINGS

FIG. 1 is a diagrammatic illustration of a mechanical face seal, according to an exemplary embodiment.

FIG. 2 is a side view illustration of the mechanical face seal of FIG. 1.

FIG. 3 is a diagrammatic illustration of a mechanical face seal coated with a film, according to an exemplary embodiment.

FIG. 4 is a diagrammatic illustration of a surface-finished mechanical face seal coated with a film, according to an exemplary embodiment.

FIG. 5 is a cross-sectional illustration of a seal assembly that includes two mechanical face seals, according to an exemplary embodiment.

FIG. 6A and FIG. 6B are diagrammatic illustrations of an earth-boring bit, according to an exemplary embodiment.

FIG. 7 is a flow chart illustrating a method of coating a mechanical face seal, according to an exemplary embodiment.

### DETAILED DESCRIPTION

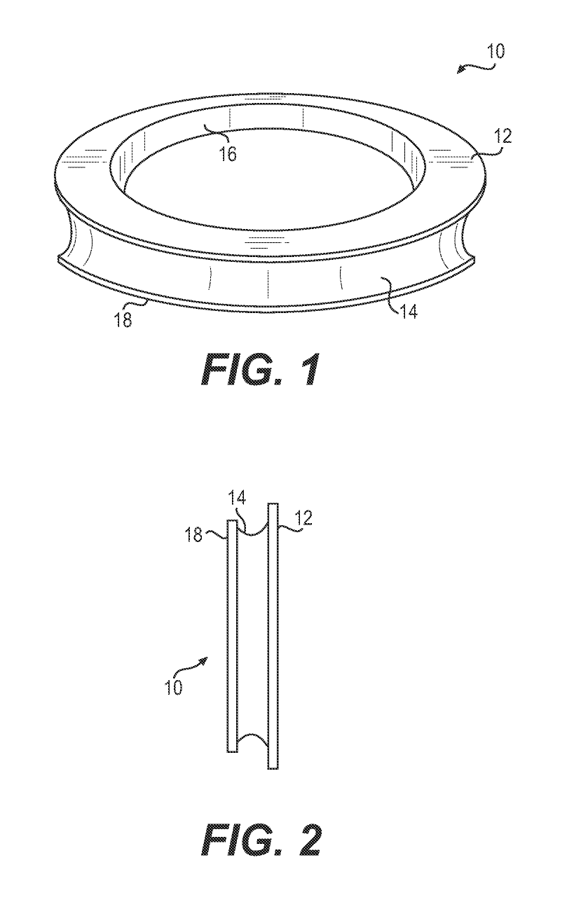

FIG. 1 illustrates a mechanical face seal 10, according to an exemplary embodiment. A side view illustration of seal 10 is shown in FIG. 2.

Seal 10 may include a first surface 12 disposed in a plane generally parallel to a second surface 18. Seal 10 may further include an inner surface 16 and an outer surface 14. Surface 14 may include a groove having a predetermined depth and a predetermined sidewall profile. For example, the groove may include a bottom fiat portion and curved sidewalls.

Seal 10 may be made hardened or tempered steel, or other materials suitable for fabricating mechanical face seals. By way of example, such materials may be iron, nickel, cobalt and alloys thereof, such as martensitic stainless steel or stainless steel. Further, seal 10 may be made of a ceramic material, which may provide protection from corrosion. Furthermore, while FIG. 1 illustrates surface 12 as a substantially flat surface, in other embodiments surface 12 may include a first area that is substantially parallel to surface 18 and a second area that is tapered at an angle with respect to the first area.

Surface 12 may also be finished with a specialized surface finishing process. In one exemplary embodiment, surface 12 may be machined. In another exemplary embodiment, the specialized finishing process may be isotropic finishing. Isotropic finishing removes asperities that may be present on surface 12. Isotropic finishing is also designed to leave valleys within surface 12. These valleys may provide improved lubricant retention in applications where seal 10 is used in a seal assembly (as will be described below). Furthermore, isotropic finishing may render surface 12 substantially more resistant to corrosion than a machined or a bare surface 12.

The isotropic finishing process may be controlled to impart a predetermined metrology to surface 12. The pre-determined metrology may be a “broken-in” metrology. A surface that is broken-in experiences less heat and less wear when it is in contact with and moving against another surface.

A metrology of surface 12 may be characterized, for example, as a measure of the roughness of surface 12 following the isotropic finishing process. For example, a measure of roughness may be calculated using the height variation on a segment (i.e. on a line profile) of surface 12. Alternatively, a measure of roughness may be calculated using the height variation in a selected area (i.e. on an area profile) of surface 12. A line profile may be obtained using, for example, a stylus profilometer. On the other hand, an area profile may be obtained, for example, using an interferometric profilometer.

By way of example only, an arithmetic average of the heights measured along a segment of surface 12 may be used to calculate a profile roughness parameter (Ra). Similarly, an arithmetic average of the heights measured in the area profile may be used to compute area roughness parameters (Sa). The isotropic finishing process may be controlled to yield predetermined Ra and Sa parameters. In general, however, a metrology of surface 12 may be any measureable characteristics or property of surface 12 following the isotropic finishing process.

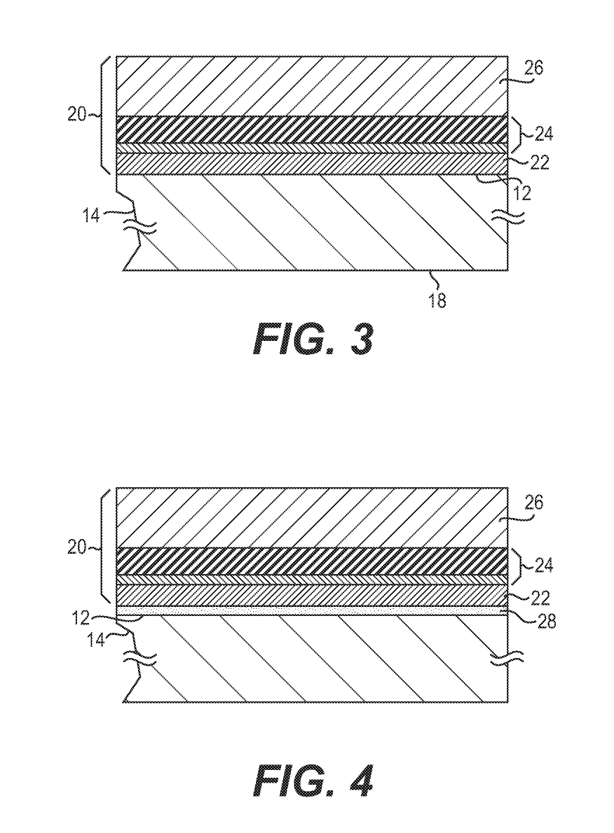

Seal 10 may include a conformal film 20 (shown FIGS. 3 and 4) disposed on at least one of surface 12 and surface 18. Film 20 may be disposed on all surfaces of seal 10. In embodiments where surface 12 includes a tapered portion, film 20 may be disposed on the tapered portion as well as on the flat portion. Film 20 may include an adhesion layer, a transition layer, and a top layer that is an amorphous diamond-like carbon layer. Film 20 may be disposed on machined and/or finished surface 12 and/or surface 13, and it may partially cover or entirely cover these surfaces.

FIG. 3 illustrates a cross-sectional view of an exemplary embodiment where seal 10 has film 20 disposed on surface 12. Film 20 includes a conformal adhesion layer 22, which may include a metal. By way of example only, adhesion layer 22 may include Chromium (Cr) or Titanium (Ti).

The term “conformal” is used herein to indicate a property of a thin film to retain the topography of its substrate. That is, adhesion layer 22 will have the same surface asperities as surface 12 because adhesion layer 22 is conformal to surface 12. Stated otherwise, adhesion layer 22. has a metrology that is substantially equal to the metrology of surface 12.

A conformal transition layer 24 is disposed on adhesion layer 22. Transition layer 24 may contain metal-doped carbon films, Fig, 3 illustrates an exemplary embodiment where transition layer 24 includes a carbon-rich layer doped with Tungsten (W) and Chromium (Cr), By way of example only, the metal content of transition layer 24 may be within the range from approximately 5 to 20 atomic percent (at %). Metal content greater than 20 atomic percent may increase the hardness of film 20 but may also result in a larger coefficient of friction. Conversely, metal content less than 5% may provide insufficient adhesion and film hardness. The carbon content of transition layer 24 may include non-hydrogenated carbon and/or hydrogenated-carbon atoms.

In a different embodiment, transition layer 24 may include a metal-doped diamond-like carbon (m-DLC) layer. Diamond-like carbon films are a type of meta-stable amorphous carbon or hydrocarbon with properties similar to those of diamond. A DLC film has the benefit of having deposition temperatures that do not exceed the lowest transformation temperature of the substrate onto which it is deposited. The transformation temperature is a temperature at which seal ring 10 at least partially loses one or more structural properties, such has its hardness or residual stress.

Film 20 may further include a conformal amorphous diamond-like carbon (a-DLC) layer 26 disposed on transition layer 24. Amorphous diamond-like carbon (a-DLC) belongs to a material family possessing low friction, high wear resistance, high scuffing resistance, and high galling resistance compared to steel. Further, a-DLC, as used herein, refers to all types of free, reactive carbon that do not have a crystalline structure.

The a-DLC layer 26 has no metal content. In other embodiments, film 20 may include amorphous hydrogenated carbon (a-C:H) disposed onto transition layer 24 instead of an a-DLC layer 26 like the one in the embodiment depicted in FIG. 3. In yet other embodiments, the a-DLC layer 26 may also be doped with transition metal carbides or other elements, such as silicon, In these cases, the carbon content of the a-DLC layer 26 may within a range from approximately 60-80 atomic percent (at %).

In other embodiments, film 20 may include an adhesion layer 22 that is Chromium (Cr), a transition layer 24 that is Tungsten-DLC (W-DLC), and an a-DLC layer 26. In yet other embodiments, film 20 may include an adhesion layer 22 that is Chromium (Cr), a transition layer 24 that includes Tungsten-doped carbon (WC) and Tungsten-DLC (W-DLC), and an amorphous hydrogenated carbon (a-C:H) layer disposed on top of transition layer 24. In other embodiments, film 20 may include a metallic layer, a metal-doped carbon layer, and an amorphous diamond-like (a-DLC) layer. The metal-doped carbon layer may be chromium-doped or tungsten-doped.

Film 20 may include an adhesion layer 22 that is deposited to a first thickness, a transition layer that is deposited to a second thickness, and a top layer that is deposited to a third thickness. The first thickness may be within the range of approximately 100 nm to 200 nm, the second thickness may be within the range of approximately 200 am to 600 nm, and the third thickness may be within the range of approximately 2,000 nm to 3,000 nm. In other embodiments, the third thickness may be within the range of approximately 2,000 nm to 10,000 nm. The first thickness, the second thickness, and the third thickness may be unequal.

In other embodiments, the third thickness may be more than three times the first thickness and more than two times the second thickness. Thinner films may be more conformal than thicker films. As such, a metrology of film 20 may he altered relative to a metrology of surface 12 simply by increasing the thickness of film 20, thereby negating the effects of any surface finishing of surface 12. Further, increasing the thickness of film 20 may yield increased residual stress, which may lower the adhesion of film 20 to surface 12.

FIG. 4 shows another exemplary embodiment similar to the embodiment depicted in FIG. 3. The exemplary embodiment of FIG. 4 differs from the one of FIG. 3 in that surface 12 is isotropic-finished. That is, surface 12 has peaks and valleys (denoted with numeral 28 in FIG. 4) scattered across it as a result of the isotropic finishing process. As such, since adhesion layer 22, transition layer 24, and layer 26 are all conformal, film 20 is also conformal. In other words, film 20 retains the metrology of isotropic-finished surface 12. In one embodiment, a surface roughness parameter Ra of isotropic-finished surface 12 may be less than about 500 nm, 200 nm, or 100 nm, Low Ra values may provide increased adhesion of film 20 to surface 12.

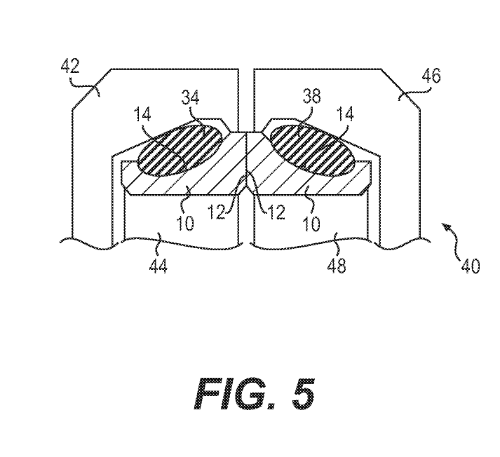

FIG. 5 illustrates a cross-sectional view of a seal assembly 40 that utilizes two mechanical face seals 10, according to an exemplary embodiment. Each surface 12 of each seal 10 in assembly 40 may be coated with a film like film 20. In another embodiment, only one seal 10 of the assembly may have film 20 coated thereon.

Seal assembly 40 includes torics 34 and 38 that serve to load each of the seals 10. Torics 34 and 38 may be made of polymeric materials. For example, torics 34 and 38 may be nitrile-based elastomers or silicone-based elastomers. While torics 34 and 38 are shown to have an oval or circular cross-section, other cross-sections are possible. Torics 34 and 38 help in maintaining a sealed interface between the surfaces 12 of each seals 10. Each surface 12 may be lubricated prior to assembling the seals 10 as depicted in FIG. 5.

Further, seal assembly 40 may include fixtures 42, 44, 46, and 48, which may be used to further maintain the sealed interface. In some applications, one seal 10 is stationary while the other seal 10 rotates with respect to the stationary seal 10. While FIG. 5 depicts an embodiment where two seals 10 are used, other embodiments may include one seal 10 whose surface 12 is mated with another metallic surface that is not that of a mechanical face seal. In that embodiment, a sealed interface also exists between surface 12 of seal 10 and the other metallic surface. Such an example embodiment is discussed below.

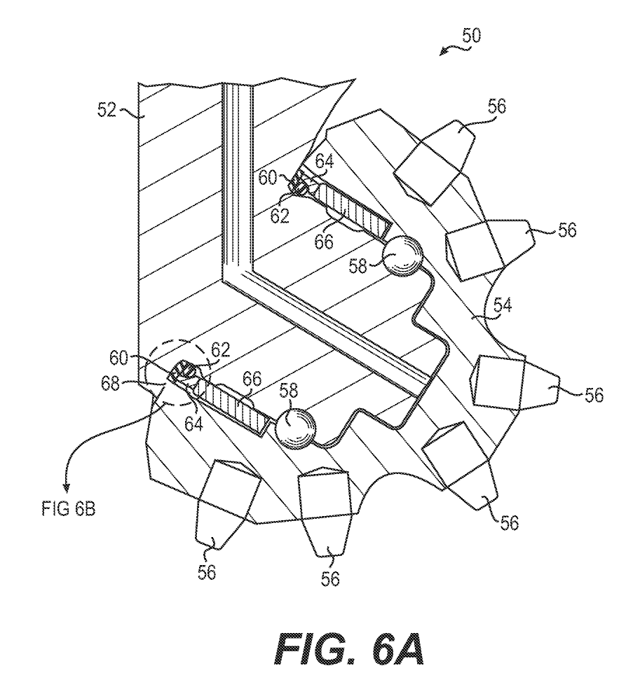

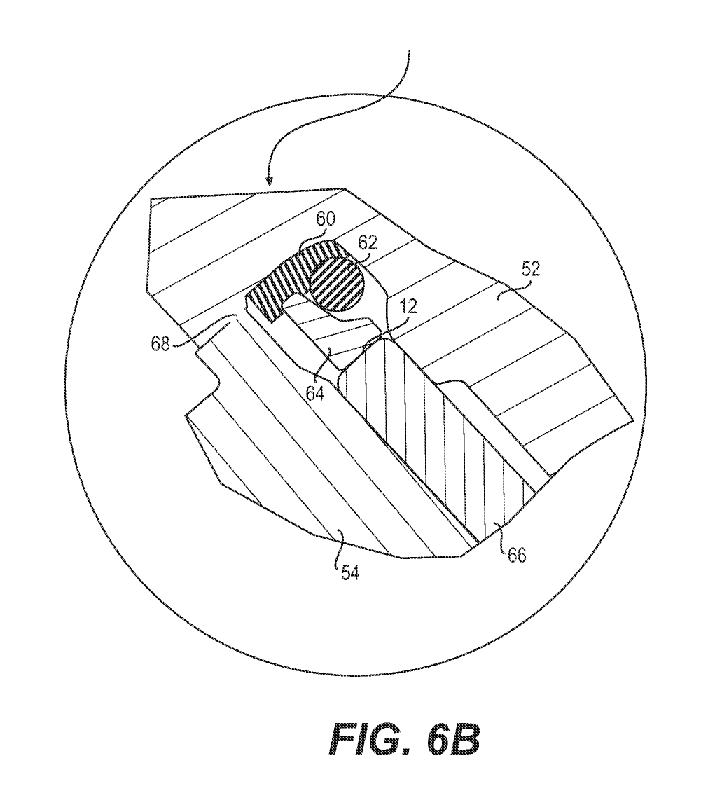

FIG. 6A shows a portion of an earth-boring bit 50, according to an embodiment. FIG. 6B is a close up view of an exemplary embodiment of a seal assembly included in earth-boring bit 50.

Earth-boring bit 50 includes a hit leg 52 supported by a shaft and a cone 54 that is mounted rotatably to the shaft (and bit leg 52). Cone 54 includes a plurality of teeth 56 disposed on its periphery for cutting and crushing earthen formations upon the rotation of cone 54. Cone 54 is retained on the shaft using a plurality of precision-ground ball locking members 58. A small gap 68 exists between cone 54 and bit leg 52.

Bit leg 52 includes fixture 60, topic 62, and a mechanical face seal 64 like the mechanical face seal 10 previously discussed. Cone 54 includes a bearing sleeve 66 that forms a sealed interface with seal 64. During operation, cone 54 rotates with respect to bit leg 52. As such, bearing sleeve 66 rotates while seal 64 remains stationary. The mating surfaces of seal 64 and bearing sleeve 66 may be coated with a film like film 20. In one embodiment, only one of the mating surfaces may be coated with film 20.

### INDUSTRIAL APPLICABILITY

The disclosed seal may be applicable to any work machine that includes mechanical face seals and/or mechanical face seal assemblies. For example, the disclosed seal may be used in rollers, cutters, excavators, earth-boring machines, under-carriage track assemblies, and any work machines used in mining applications.

The disclosed seal may have various advantages over prior art seals. For example, the disclosed seal may have an extended lifetime, especially in applications where seals and seal assemblies are subjected to high static and transient pressure gradients, high rotational velocities, and corrosive and abrasive environments.

Specifically, the disclosed seal may have higher weep, score, and leak revolutions-per-minute (RPM) ratings, The weep rpm rating is the rotational speed at which lubricant is visible at the sealed interface of a seal assembly. The leak rpm rating is the rotational speed at which lubricant leaks from the interface, and the score rpm rating is the rotational speed at which both mating surfaces are in contact with no lubricant in between, in other words, the disclosed film may have superior adhesion properties and may not delaminate under conditions that would cause delamination in prior art uncoated or DLC-coated seals such as the coated seal disclosed in the '541 patent.

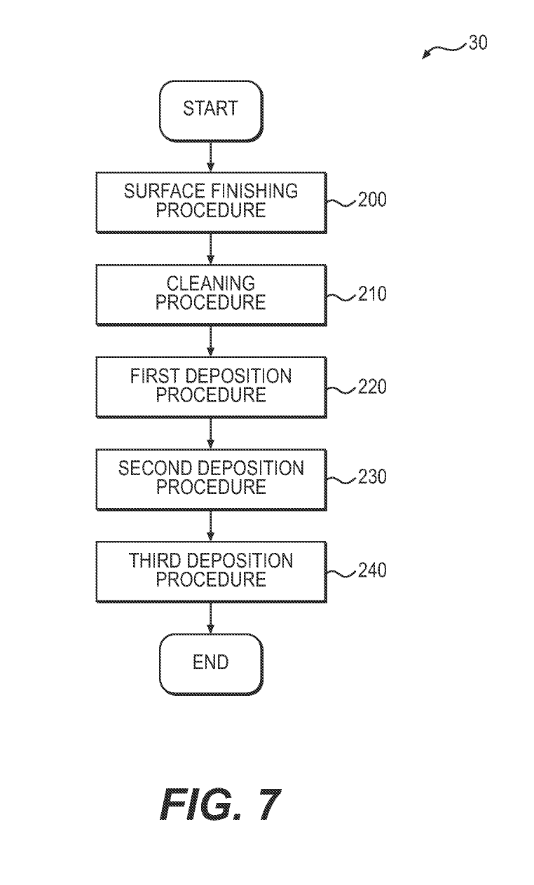

FIG. 7 is a flow chart depicting an exemplary method 30 of depositing film 20 on the disclosed seal, For simplicity, method 30 is described in the context of coating surface 12 of seal 10 with film 20. However, one of skill in the art will readily recognize that method 30 may be applied to any surface of seal 10. Further, while method 30 discloses depositing film 20 on the entirety of surface 12, other embodiments of method 30 may include additional procedures that result in film 20 being coated only on a portion of surface 12. Such additional procedures may include, for example, shadow masking, photolithography and wet etching, lift-off, laser ablation, and ion-beam milling.

Method 30 may include a surface finishing procedure 200, which may be at least one of isotropic finishing, mechanical polishing, break-in polishing, burnishing, lapping, chemical-mechanical planarization, machining, micromachining, or any combinations thereof. Surface finishing procedure 200 may include carburizing surface 12, In another embodiment, surface finishing procedure 200 may he for example an isotropic finishing procedure that is tuned to yield a predetermined surface roughness parameter Ra. For example, a predetermined surface roughness may be an Ra value that less than about 500 nm, 200 nm, or 100 nm. As previously discussed, a low Ra value may provide increased adhesion of film 20 to surface 12.

An example isotropic finishing process may be, for example, immersing surface 12 in a chemical bath that includes an oxalic acid-based solution. The solution oxidizes asperities that may be present on surface 12. The chemical bath may also include inert and nonabrasive micro-particles that may further contribute in removing the oxidized surface asperities, simply from the mechanical interactions resulting from localized flows of the bath. Following the chemical treatment, surface 12 maybe burnished to reduce the height of the oxidized asperities. The chemical bath may be stirred or shaken to improve reaction rates. For example, process parameters such as the pH of the bath, the amplitude of the vibrational energy imparted to the bath from shaking it or stirring it, or the exposure time may all be independently controlled to yield a predetermined surface roughness to surface 12. One of ordinary skill in the art will readily recognize that other process parameters may be controlled to achieve a desired roughness since optimal parametric spaces may be determined empirically. Further, finishing procedure 200 may be tuned to yield predetermined metrologies other than surface roughness. That is, finishing procedure 200 may be tuned to yield a predetermined value of a measureable characteristic or property of surface 12, following the isotropic finishing process.

Additionally, method 30 may include a cleaning procedure 210. Cleaning procedure 210 may be used to rid surface 12 of contaminants. Thus, cleaning procedure 210 may be any procedure that removes particulates from surface 12. By way of example only, cleaning procedure 210 may be a chemical bath that includes solvents such as isopropyl alcohol (IPA). Alternatively, cleaning procedure 210 may be a plasma treatment. For example, Oxygen or Argon plasmas may be used to clean surface 12. Further, while FIG. 7 depicts cleaning procedure 210 being conducted after surface finishing procedure 200, one of ordinary skill in the art will readily appreciate that cleaning procedure 210 may be conducted following any other procedures conducted during method 30. Furthermore, cleaning procedure 210 may be conducted in situ (i.e. within a deposition chamber) or ex situ (i.e. prior to loading seal 10 in a deposition chamber).

Additionally, method 30 may include a first deposition procedure 220. First deposition procedure 220 may include depositing an adhesion layer on surface 12 such as the adhesion layer 22 described in the exemplary embodiments shown in FIGS. 3 and 4. Specifically, first deposition procedure 220 may include metal deposition using physical vapor deposition (PVD) sputtering.

In PVD sputter deposition, inert ions (e.g. Ar⁺) are accelerated using a DC or an RF drive through a potential gradient so that they bombard a target, generating ejected clusters of the target material by transfer of momentum. The ejected clusters adsorb onto a surface to be coated that is placed near the target, and they produce a thin film of the target material.

PVD sputter deposition occurs in a vacuum deposition chamber, and the surface that is to be coated may be heated. PVD sputtering deposition parameters like deposition time, substrate temperature, chamber pressure, gas flow rates, among others, may be optimized to yield a film having a desired thickness. First deposition procedure 220 may be used to coat surface 12 with an adhesion layer 22 made either of Chromium (Cr) or Titanium (Ti).

Additionally, method 30 may include a second deposition procedure 230 for depositing a transition layer like transition layer 24 on surface 12 that is already coated with an adhesion layer. Second deposition procedure 230 may include a PVD sputter deposition process. In another embodiment, second deposition procedure 230 may include a reactive PVD sputter deposition is a type of PVD sputtering process where a reactive precursor compound is introduced in the deposition chamber during sputter deposition.

Second deposition procedure 230 may include a reactive PVD sputtering process that produces a transition layer that includes Tungsten-DLC (W-DLC). In another embodiment, second deposition procedure 230 may include a reactive PVD sputtering process that produces a transition layer that includes Tungsten-doped carbon (WC) and Tungsten-DLC (W-DLC). In yet another embodiment, second deposition procedure 230 may include a reactive PVD sputtering process that produces only a Tungsten-DLC (W-DLC) layer. In general, second deposition procedure 230 may include a PVD sputtering process that produces any (or any combinations) of the films discussed with respect to transition layer 24. Further, the reactive PVD sputtering process may use a volatile hydrocarbon as the reactive compound, such as acetylene, for example.

Additionally, method 30 may include a third deposition procedure 240 that produces a top layer like layer 26. Third deposition procedure 240 may be a plasma-assisted chemical vapor deposition (PACVD) process, also known as a plasma-enhanced chemical vapor deposition (PECVD) process.

In PACVD, a plasma is generated in the deposition chamber, and volatile precursor compounds are introduced into the chamber, Thermal energy and the energy from the plasma drive the reaction rates of the volatile precursor compounds to produce the desired material onto the surface that is to be coated. In PACVD, the substrate and/or the chamber may be heated to provide the required thermal energy. In one embodiment, third deposition procedure 240 may be configured to produce an a-DLC layer. In another embodiment, third deposition procedure 240 may be a PACVD process configured to produce a-C:H layer.

Process parameters of first, second and third deposition procedures 220, 230, and 240 may be tuned to yield the respective thicknesses previously discussed with respect to adhesion layer 22, transition layer 24, and layer 26. Further, the precursor compound for the DLC-based films may be a hydrocarbon, such as acetylene or methane, for example.

It will be apparent to those skilled in the art that various modifications and variations can be made to the disclosed seal. Other embodiments will be apparent to those skilled in the art from consideration of the specification and practice of the disclosed seal. It is intended that the specification and examples be considered as exemplary only, with a true scope being indicated by the following claims and their equivalents.

What is claimed is:

1. A seal ring, comprising:
a first surface;
a second surface disposed in a plane generally parallel to the first surface;
wherein at least one of the first surface and the second surface is at least partially coated with a film that includes an adhesion layer, a transition layer, and an amorphous diamond-like (a-DLC) layer.

2. The seal ring of claim 1, wherein the first surface or the second surface has a surface metrology characteristic of an isotropic finishing process.

3. The seal ring of claim 1, wherein the film is conformal.

4. The seal ring of claim 1, wherein the adhesion layer comprises Chromium.

5. The seal ring of claim 1, wherein the transition layer comprises Tungsten and carbon.

6. The seal ring of claim 1, wherein the transition layer comprises a metal and carbon.

7. The seal ring of claim 1, wherein the transition layer comprises a metal and a diamond-like carbon film.

8. The seal ring of claim 1, wherein the transition layer has a metal content within a range from approximately 5 to 20 atomic percent (at %).

9. The seal ring of claim 2, wherein the a-DLC layer is disposed overtop the transition layer, the transition layer overtop the adhesion layer, and the adhesion layer on at least one of the first surface and the second surface.

10. A method of depositing a film on a surface of a seal, comprising:
finishing the surface to impart a predetermined geometry and/or a predetermined metrology to the surface;
cleaning the surface after finishing;
depositing a first layer on the surface after cleaning using physical vapor deposition (PVD) sputtering, the first layer including a metal;
depositing a second layer on the first layer using PVD sputtering, the second layer including a metal and carbon; and
depositing a third layer on the second layer using plasma-assisted chemical vapor deposition (PACVD), the third layer being an amorphous diamond-like carbon (a-DLC) layer.

11. The method of claim 10, wherein the first layer comprises Chromium.

12. The method of claim 10, wherein the second layer comprises Chromium-doped and Tungsten-doped carbon.

13. The method of claim 12, wherein the metal content of the second layer is within a range from approximately 5 to 20 atomic percent (at %).

14. The method of claim 10, wherein the finishing includes machining the surface.

15. The method of claim 10, wherein the finishing includes an isotropic finishing process.

16. The method of claim 10, wherein the first layer is deposited to a first thickness, the second layer to a second thickness, and the third layer to a third thickness, and the first, second, and third thicknesses are unequal.

17. The method of claim 16, wherein the third thickness is more than three times the first thickness and more than two times the second thickness.

18. The method of claim 17, wherein the third thickness is approximately 10 μm.

19. The method of claim 10, wherein the finishing includes carburizing the surface.

20. An earth-boring bit, comprising:
a bit leg supported by a shaft, the bit leg including a seal having a first surface;
a cone rotatably mounted to the shaft, the cone including a bearing sleeve having a second surface;
wherein at least one of the first surface and the second surface are coated with a thin film that includes a metallic layer, a metal-doped carbon layer, and an amorphous diamond-like (a-DLC) layer.
